(19) United States
(12) Patent Application Publication
(10) Pub. No.: US 2025/0374540 A1
(43) Pub. Date: Dec. 4, 2025

(54) MICROELECTRONIC DEVICES, AND RELATED METHODS AND MEMORY DEVICES

(71) Applicant: Micron Technology, Inc., Boise, ID (US)

(72) Inventors: Yifen Liu, Meridian, ID (US); Ching-Huang Lu, Fremont, CA (US); Yuhong Qian, Singapore (SG); Yuan Fang, Singapore (SG)

(21) Appl. No.: 19/197,497

(22) Filed: May 2, 2025

Related U.S. Application Data
(60) Provisional application No. 63/655,334, filed on Jun. 3, 2024.

(51) Int. Cl. H10B 41/27; H10B 41/10; H10B 41/50; H10B 43/10; H10B 43/27; H10B 43/50

(52) U.S. Cl. CPC H10B 41/27; H10B 41/10; H10B 41/50; H10B 43/10; H10B 43/27; H10B 43/50

(57) ABSTRACT

A microelectronic device includes a stack structure, pillar structures, and insulative slot structures. The stack structure includes blocks horizontally extending in parallel in a first direction and individually having tiers respectively including conductive material and insulative material vertically neighboring the conductive material. The pillar structures vertically extend through the blocks of the stack structure. The pillar structures respectively include a void space horizontally interposed between dielectric material and additional dielectric material. The insulative slot structures horizontally extend in parallel in the first direction. The insulative slot structures respectively horizontally overlap and vertically extend into a group of the pillar structures. Related methods, memory devices, and electronic systems are also described.

### CROSS-REFERENCE TO RELATED APPLICATIONS

This application claims the benefit under 35 U.S.C. § 119 (e) of U.S. Provisional Patent Application Ser. No. 63/655,334, filed Jun. 3, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, electronic systems, and additional methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more decks (e.g., stack structures) including tiers of conductive structures and dielectric materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

### BRIEF DESCRIPTION OF THE DRAWINGS

FIG. 1A is a simplified, vertical cross-sectional view of a portion A of a microelectronic device structure at a processing stage of a method forming a microelectronic device, in accordance with embodiments of the disclosure. FIG. 1B is a simplified, partial top-down view of the microelectronic device structure at the processing stage of FIG. 1A, wherein the portion A shown in FIG. 1A is about dashed-line A-A depicted in FIG. 1B. FIG. 1C shows a magnified view of a section B (identified with a dashed box in FIG. 1B) of the simplified, partial top-down view of the microelectronic device structure shown in FIG. 1B.

FIG. 2A is a simplified, vertical cross-sectional view of the portion A of the microelectronic device structure shown in FIGS. 1A and 1B at another processing stage of the method forming the microelectronic device following the processing stage of FIGS. 1A through 1C. FIG. 2B shows a magnified view of the section B shown in FIGS. 1B and 1C at the processing stage of FIG. 2A.

FIG. 3A is a simplified, vertical cross-sectional view of the portion A of the microelectronic device structure shown in FIGS. 1A and 1B at another processing stage of the method forming the microelectronic device following the processing stage of FIGS. 2A and 2B. FIG. 3B shows a magnified view of the section B shown in FIGS. 1B and 1C at the processing stage of FIG. 3A.

FIG. 4 is a simplified, partial cutaway perspective view of a microelectronic device, in accordance with an embodiment of the disclosure.

FIG. 5 is a simplified, schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{y}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, a “semiconductor structure” or a “semiconductor structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

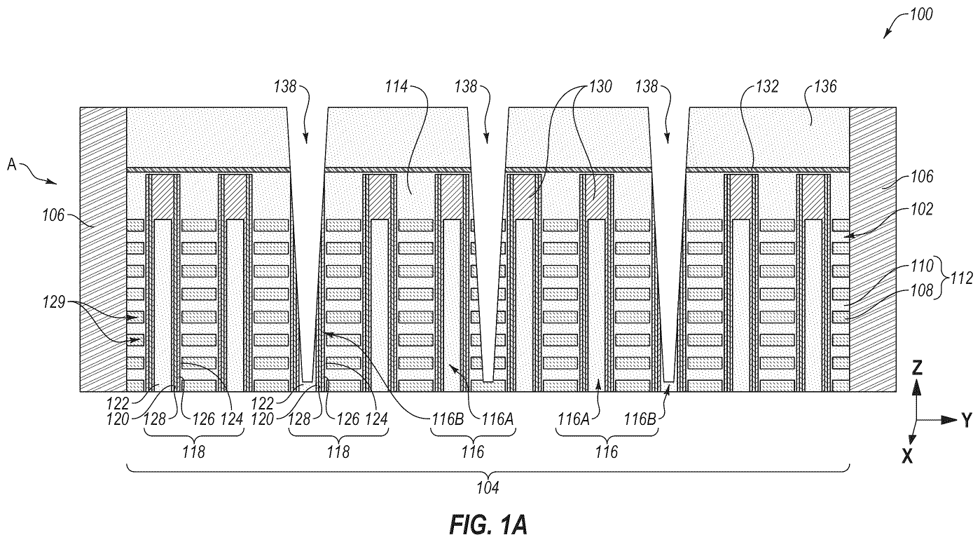

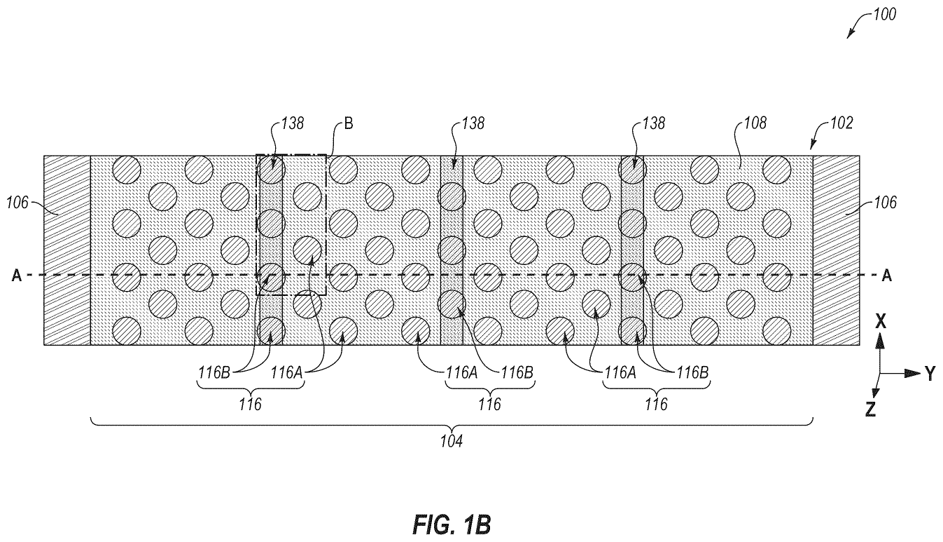

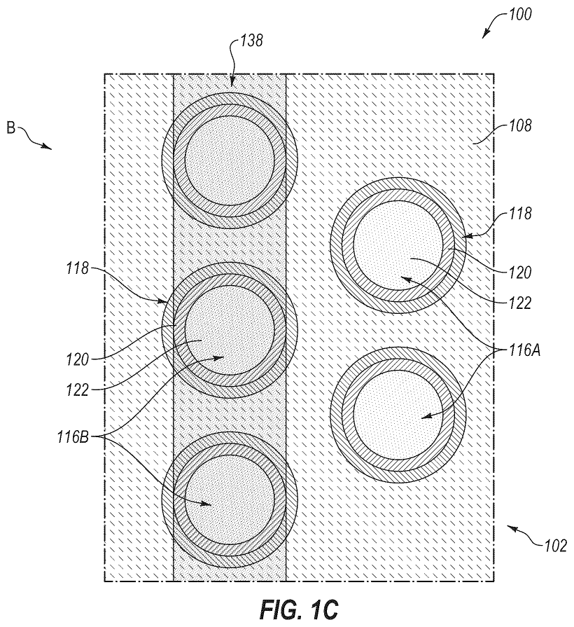

FIG. 1A through FIG. 3B are various views (described in further detail below) illustrating a microelectronic device structure at different processing stages of a method of forming a microelectronic device (e.g., a memory device, such as a 3D NAND Flash memory device), in accordance with embodiments of the disclosure. With the description provided below, it will be readily apparent to one of ordinary skill in the art that the methods described herein may be used for forming various devices. In other words, the methods of the disclosure may be used whenever it is desired to form a microelectronic device.

FIG. 1A is a simplified, vertical cross-sectional view of a portion A of a microelectronic device structure 100 at a processing stage of the method forming a microelectronic device, in accordance with embodiments of the disclosure. As shown in FIG. 1A, the microelectronic device structure 100 may be formed to include a stack structure 102 including a vertically alternating (e.g., in a Z-direction) sequence of conductive material 108 and insulative material 110 arranged in tiers 112. The tiers 112 of the stack structure 102 may respectively include the conductive material 108 vertically neighboring the insulative material 110. In addition, the stack structure 102 may be divided (e.g., segmented, partitioned) into blocks 104 separated from one another by slot structures 106. The slot structures 106 may vertically extend (e.g., in the Z-direction) completely through the stack structure 102, as well as through a first dielectric material 114, a second dielectric material 132, and a third dielectric material 136 formed to vertically overlie the stack structure 102. Within horizonal areas of the blocks 104, the microelectronic device structure 100 may further include cell pillar structures 116 vertically extending through the tiers 112 of the stack structure 102, and slots 138 (e.g., slits, openings) horizontally overlapping (e.g., in the Y-direction) and vertically extending (e.g., in the Z-direction) into some of the cell pillar structures 116. Additional features (e.g., materials, structures, devices) of the microelectronic device structure 100 are described in further detail below. FIG. 1B is a simplified, partial top-down view of the microelectronic device structure 100 at the processing stage of FIG. 1A, wherein the portion A shown in FIG. 1A is about dashed-line A-A depicted in FIG. 1B. FIG. 1C shows a magnified view of a section B (identified with a dashed box in FIG. 1B) of the simplified, partial top-down view of the microelectronic device structure 100 shown in FIG. 1B.

The insulative material 110 of respective tiers 112 of the stack structure 102 may be formed of and include at least one dielectric material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative material 110 of each of the tiers 112 of the stack structure 102 is formed of and includes a dielectric oxide material, such as SiOₓ (e.g., SiO₂). The insulative material 110 of each of the tiers 112 may be substantially homogeneous, or the insulative material 110 of one or more (e.g., each) of the tiers 112 may be heterogeneous.

The conductive material 108 of respective tiers 112 of the stack structure 102 may be formed of and include at least one conductive material suitable for use within access line structures (e.g., local access line structures, local word line structures) and select gate structures (e.g., lower select gate structures, such as source-side select gate (SGS) structures; upper select gate structures, such as drain-side select gate (SGD) structures) of a microelectronic device of the disclosure. By way of non-limiting example, the conductive material 108 of the tiers 112 of the stack structure 102 may respectively be formed of and include one or more of at least one metal, at least one alloy, at least one conductive metal-containing material, and at least one conductively doped semiconductor material. In some embodiments, the conductive material 108 of the tiers 112 of the stack structure 102 is formed of and includes W. In additional embodiments, the conductive material 108 of the tiers 112 of the stack structure 102 is formed of and includes Mo. In addition, optionally, for an individual tier 112 of the stack structure 102, at least one liner material (e.g., at least one insulative liner material, at least one conductive liner material) may be formed around the conductive material 108 thereof. The liner material may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material comprises at least one additional conductive material employed as a seed material for the formation of the conductive material. In some embodiments, the liner material comprises titanium nitride (TiNₓ, such as TiN). In further embodiments, the liner material further includes aluminum oxide (AlOₓ, such as Al₂O₃). As a non-limiting example, AlOₓ (e.g., Al₂O₃) may be formed directly adjacent the insulative material 110, TiNₓ (e.g., TiN) may be formed directly adjacent the AlOₓ, and W may be formed directly adjacent the TiNₓ.

The conductive material 108 of some relatively vertically higher ones of the tiers 112 (e.g., at least two (2) uppermost of the tiers 112, at least four (4) uppermost of the tiers 112, at least eight (8) uppermost of the tiers 112) of the stack structure 102 may form and define drain-side select gate (SGD) structures of the microelectronic device structure 100. In addition, the conductive material 108 of one or more relatively vertically lower ones of tiers 112 (e.g., at least one (1) lowermost of the tiers 112, at least two lowermost of the of the tiers 112) may form and define one or more source-side select gate (SGS) structures of the microelectronic device structure 100. Moreover, the conductive material 108 of further ones of the tiers 112 may form and define local word line structures (e.g., local access line structures) of the microelectronic device structure 100. Furthermore, the conductive material 108 of yet further ones of the tiers 112 may form and define source-side gate-induced drain-leakage (GIDL) generation (GG) structures and/or drain-side GG structures of the microelectronic device structure 100.

The stack structure 102 may be formed to include any desired number of the tiers 112. By way of non-limiting example, the stack structure 102 may be formed to include greater than or equal to sixteen (16) of the tiers 112, such as greater than or equal to thirty-two (32) of the tiers 112, greater than or equal to sixty-four (64) of the tiers 112, greater than or equal to one hundred twenty-eight (128) of the tiers 112, or greater than or equal to two hundred fifty-six (256) of the tiers 112.

Still referring to FIG. 1A, the blocks 104 of the stack structure 102 may horizontally extend parallel in an X-direction (e.g., a first horizontal direction). As used herein, the term “parallel” means substantially parallel. Horizontally neighboring blocks 104 of the stack structure 102 may be separated from one another in a Y-direction (e.g., a second horizontal direction) orthogonal to the X-direction by the slot structures 106. The slot structures 106 may also horizontally extend parallel in the X-direction. Each of the blocks 104 of the stack structure 102 may exhibit substantially the same geometric configuration (e.g., substantially the same dimensions and substantially the same shape) as each other of the blocks 104, or one or more of the blocks 104 may exhibit a different geometric configuration (e.g., one or more different dimensions and/or a different shape) than one or more other of the blocks 104. In addition, each pair of horizontally neighboring blocks 104 of the stack structure 102 may be horizontally separated from one another by substantially the same distance (e.g., corresponding to a width in the Y-direction of each of the slot structures 106) as each other pair of horizontally neighboring blocks 104 of the stack structure 102, or at least one pair of horizontally neighboring blocks 104 of the stack structure 102 may be horizontally separated from one another by a different distance than that separating at least one other pair of horizontally neighboring blocks 104 of the stack structure 102. In some embodiments, the blocks 104 of the stack structure 102 are substantially uniformly (e.g., substantially non-variably, substantially equally, substantially consistently) sized, shaped, and spaced relative to one another.

With continued reference to FIG. 1A, the cell pillar structures 116 may each individually be formed of and include multiple (e.g., a plurality of) materials facilitating the formation of vertically extending (e.g., in the Z-direction) strings 210 of memory cells 129. By way of non-limiting example, each of the cell pillar structures 116 may individually be formed to include an outer material stack 118, channel material 120 inwardly horizontally adjacent the outer material stack 118, and fill material 122 inwardly horizontally adjacent the channel material 120.

The cell pillar structures 116 may include first cell pillar structures 116A and second cell pillar structures 116B. The first cell pillar structures 116A may comprise “active” cell pillar structures configured to form vertically extending strings of memory cells in electrical communication with other features (e.g., control logic circuitry) of a microelectronic device of the disclosure. The second cell pillar structures 116B may comprise “dummy” cell pillar structures (also referend to as “inactive” cell pillar structures) having a configuration to that of the first cell pillar structures 116A, but forming “inactive” vertically extending strings of memory cells that are not in electrical communication with other features (e.g., the control logic circuitry) of the microelectronic device of the disclosure.

As previously mentioned, the cell pillar structures 116 may respectively be formed of and include a stack of materials including the outer material stack 118, the channel material 120, and the fill material 122. The outer material stack 118 may include a charge-blocking material 124, such as first dielectric oxide material (e.g., SiOₓ, such as SiO₂; AlOₓ, such as Al₂O₃); a charge-trapping material 126, such as a dielectric nitride material (e.g., SiN_{y}, such as Si₃N₄); a tunnel dielectric material 128, such as a second oxide dielectric material (e.g., SiOₓ, such as SiO₂). The a channel material 120 may be formed of and include semiconductor material (e.g., silicon, such as polycrystalline silicon). The fill material 122 may be formed of and include dielectric material (e.g., dielectric oxide, dielectric nitride, air). The charge-blocking material may be formed on or over, and may substantially cover, surfaces of the microelectronic device structure 100 defining boundaries (e.g., horizontal boundaries, lower vertical boundaries) of the cell pillar structures 116, such as surfaces of the insulative material 110 and the conductive material 108 of the tiers 112 of the stack structure 102. The charge-trapping material 126 may be formed on or over inner surfaces of the charge-blocking material 124. The tunnel dielectric material 128 may be formed on or over inner surfaces of the charge-trapping material 126. The channel material 120 may be formed on or over inner surfaces of the tunnel dielectric material 128. The dielectric fill material may be formed on or over inner surfaces of the channel material 120.

Referring to FIG. 1B, the microelectronic device structure 100 may be formed to includes a hexagonal pattern (e.g., a hexagonal arrangement, a hexagonal grid, a hexagonal array) of the cell pillar structures 116. The hexagonal pattern may exhibit a repeating horizontal arrangement of seven (7) cell pillar structures 116, wherein one (1) of the seven (7) cell pillar structures 116 is substantially horizontally centered between six (6) other of the seven (7) cell pillar structures 116. The hexagonal pattern exhibits three (3) different axes of symmetry (e.g., a first axis of symmetry, a second axis of symmetry, and a third axis of symmetry) in the same horizontal plane (e.g., the XY plane) about a center of the horizontally centered cell pillar structure 116 of the seven (7) cell pillar structures 116. Different axes of symmetry directly radially adjacent to one another may be radially separated from one another by an angle of about 60 degrees.

Intersections of some of the cell pillar structures 116 (e.g., the first cell pillar structures 116A) and the conductive material 108 of some of the tiers 112 of the stack structure 102 may define vertically extending strings of memory cells 129 coupled in series with one another within the microelectronic device structure 100. In some embodiments, the memory cells 129 formed at the intersections of the conductive material 108 of some of the tiers 112 and some of the cell pillar structures 116 comprise so-called “MONOS” (metal-oxide-nitride-oxide-semiconductor) memory cells. In additional embodiments, the memory cells 129 comprise so-called “TANOS” (tantalum nitride—aluminum oxide—nitride—oxide—semiconductor) memory cells, or so-called “BETANOS” (band/barrier engineered TANOS) memory cells, each of which are subsets of MONOS memory cells. In further embodiments, the memory cells comprise so-called “floating gate” memory cells including floating gates (e.g., metallic floating gates) as charge storage structures. The floating gates may horizontally intervene between central structures of some of the cell pillar structures 116 and the conductive material 108 of some of the tiers 112 of the stack structure 102.

With continued reference to FIG. 1A, contact structures 130 may be formed to contact (e.g., physical contact, electrically contact) the channel material 120 of the cell pillar structures 116. In some embodiments, portions of the contact structures 130 vertically extend into the cell pillar structures 116. As shown in FIG. 1A, for an individual contact structure 130, at least a portion of the contact structure 130 may vertically extend (e.g., in the Z-direction) beyond uppermost vertical boundaries (e.g., uppermost surfaces) of the channel material 120 of a respective cell pillar structure 116, and may be horizontally surrounded by and contact (e.g., physically contact, electrically contact) the channel material 120 of the cell pillar structure 116 at inner horizontal boundaries (e.g., inner sidewalls) of the channel material 120. In addition, for individual contact structures 130, a vertically upper portion of the contact structure 130 may be located at or vertically above uppermost boundaries of the cell pillar structure 116 (e.g., uppermost boundaries of the channel material 120 and the outer material stack 118 of the cell pillar structure 116). As shown in FIG. 1A, in some embodiments, an uppermost vertical boundary of an individual contact structure 130 is substantial coplanar with an uppermost vertical boundary of the channel material 120 of the cell pillar structure 116 operatively associated therewith.

The contact structures 130 may be formed of and include conductive material. As a non-limiting example, at least a portion (e.g., at least the vertically lower portion) of each of the contact structures 130 may be formed of and include a conductively doped semiconductor material (e.g., conductively doped polycrystalline silicon). As another non-limiting example, at least a portion (e.g., at least the vertically upper portion) of each of the contact structures 130 may be formed of and include a metal material comprising one or more of at least one metal, at least one alloy, and at least one conductive metal-containing material (e.g., a conductive metal nitride, a conductive metal silicide, a conductive metal carbide, a conductive metal oxide). Each of the contact structures 130 may individually be substantially homogeneous, or one or more of the contact structures 130 may individually be substantially heterogeneous.

Still referring to FIG. 1A, the first dielectric material 114 may be formed of and include insulative material. By way of non-limiting example, the first dielectric material 114 may be formed of and include one or more of dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), dielectric nitride material (e.g., SiN_{y}), dielectric oxynitride material (e.g., SiOₓN_{y}), dielectric oxycarbide material (e.g., SiOₓC_{y}), hydrogenated dielectric oxycarbide material (e.g., SiCₓO_{y}H_{z}), and dielectric carboxynitride material (e.g., SiOₓC_{z}N_{y}). In some embodiments, the first dielectric material 114 is formed of and includes dielectric oxide material (e.g., SiOₓ, such as SiO₂). In additional embodiments, the first dielectric material 114 is formed of and includes low-K dielectric material, such as one or more of SiOₓC_{y}, SiOₓ N_{y}, SiCₓO_{y}H_{z}, and SiOₓC_{z}N_{y}. The first dielectric material 114 may be substantially homogeneous, or the first dielectric material 114 may be heterogeneous.

The second dielectric material 132 may be formed of and include insulative material having etch selectivity relative to the first dielectric material 114 and the third dielectric material 136. In some embodiments, the second dielectric material 132 is employed as a so-called etch stop material having enhanced etch resistivity relative to the third dielectric material 136 during mutual exposure to an etchant material. In some embodiments, the second dielectric material 132 is formed of and includes dielectric nitride material (e.g., SiN_{y}, such as Si₃N₄). The second dielectric material 132 may be substantially homogeneous, or the second dielectric material 132 may be heterogeneous.

The third dielectric material 136 may be formed of and include insulative material. A material composition of the third dielectric material 136 may be different than a material composition of the second dielectric material 132. By way of non-limiting example, the first dielectric material 114 may be formed of and include one or more of dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), dielectric nitride material (e.g., SiN_{y}), dielectric oxynitride material (e.g., SiOₓN_{y}), dielectric oxycarbide material (e.g., SiOₓC_{y}), hydrogenated dielectric oxycarbide material (e.g., SiCₓO_{y}H_{z}), and dielectric carboxynitride material (e.g., SiOₓC_{z}N_{y}). In some embodiments, the third dielectric material 136 is formed of and includes dielectric oxide material (e.g., SiOₓ, such as SiO₂). The third dielectric material 136 may be substantially homogeneous, or the third dielectric material 136 may be heterogeneous.

Still referring to FIG. 1A, the slot structures 106 may comprise slots (e.g., slits, trenches, opening) at least partially (e.g., substantially) filled with insulative material, such as one or more of dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), dielectric nitride material (e.g., SiN_{y}), dielectric oxynitride material (e.g., SiOₓN_{y}), dielectric oxycarbide material (e.g., SiOₓC_{y}), hydrogenated dielectric oxycarbide material (e.g., SiCₓO_{y}H_{z}), and dielectric carboxynitride material (e.g., SiOₓC_{z}N_{y}). In some embodiments, the slot structures 106 are respectively formed of and include dielectric oxide material (e.g., SiOₓ, such as SiO₂). The slot structures 106 may individually be substantially homogeneous, or the slot structures 106 may individually be heterogeneous. As shown in FIG. 1A, in some embodiments, upper surfaces of the slot structures 106 are formed to be substantially coplanar with an upper surface of the third dielectric material 136. In additional embodiments, the upper surfaces of the slot structures 106 are formed to be vertically offset (e.g., to vertically underlie or to vertically overlie) from the upper surface of the third dielectric material 136.

Referring collectively to FIGS. 1A through IC, the slots 138 may be formed within horizontal areas of the blocks 104. The slots 138 may horizontally extend in parallel in the X-direction, and may be horizontally separated from one another in the Y-direction. In addition, the slots 138 may respectively vertically extend (e.g., in the Z-direction) completely through the third dielectric material 136, the second dielectric material 132, and the first dielectric material 114; and only partially (e.g., less than completely) through the stack structure 102. For example, an individual slot 138 may vertically terminate at or proximate a lower boundary of an upper group of the tiers 112 to be employed, at least in part, as select gate tiers (e.g., SGD tiers) of a microelectronic device (e.g., a memory device, such as a 3D NAND Flash memory device) of the disclosure. The upper group of the tiers 112 may, for example, comprise less than or equal to eight (8) of the tiers 112. For an individual tier 112 of the upper group of the tiers 112, the conductive material 108 thereof, as partitioned by the slots 138 and the slot structures 106, may form select gate structures (e.g., SGD structures) for the blocks 104. For an individual block 104 of the stack structure 102, the slots 138 may form and partially define sub-block regions of the block 104, wherein different sub-block regions of the block 104 include different select gate structures (e.g., SGD structures) than one another. As shown in FIGS. 1A and 1B, in some embodiments, three (3) slots 138 are formed within the horizontal area of an individual block 104. In additional embodiments, a different quantity (e.g., less than three, such as two; greater than three, such as four, five, or greater than five) of the slots 138 are formed within the horizontal area of an individual block 104.

The slots 138 may respectively horizontally overlap (e.g., in the Y-direction) and vertically extend (e.g., in the Z-direction) into some of the second cell pillar structures 116B (e.g., dummy cell pillar structures) of the microelectronic device structure 100. For example, the slots 138 within the horizontal area of an individual block 104 of the stack structure 102 may respectively horizontally overlap (e.g., in the Y-direction) and vertically extend (e.g., in the Z-direction) into an individual group (e.g., an individual row) of the second cell pillar structures 116B (e.g., dummy cell pillar structures) within the block 104. As shown in FIG. 1B, an individual slot 138 may horizontally overlap, in the Y-direction, an individual row of the second cell pillar structures 116B horizontally extending in the X-direction. In some embodiments, a horizontal centerline, in the Y-direction, of an individual slot 138 is substantially aligned within a horizontal centerline, in the Y-direction, of an individual row of the second cell pillar structures 116B. In additional embodiments, the horizontal centerline, in the Y-direction, of an individual slot 138 is horizontally offset from the horizontal centerline, in the Y-direction, of an individual row of the second cell pillar structures 116B. The slots 138 may also respectively horizontally overlap (e.g., in the Y-direction) and vertically extend (e.g., in the Z-direction) through an individual group (e.g., an individual row) the contact structures 130 operatively associated with (e.g., in contact with) an individual row of the second cell pillar structures 116B.

The slots 138 may respectively be horizontally offset (e.g., in the Y-direction) from the first cell pillar structures 116A (e.g., active cell pillar structures) of the microelectronic device structure 100. For example, within an individual block 104 of the stack structure 102, each of the first cell pillar structures 116A within a horizonal area of the block 104 may be horizontally offset (e.g., in the Y-direction) from each of the slots 138 within the horizonal area of the block 104. Within an individual block 104 of the stack structure 102, multiple rows of the first cell pillar structures 116A (e.g., each row horizontally extending in the X-direction) may be horizontally interposed (e.g., in the Y-direction) between a pair (e.g., two) of the slots 138 horizontally neighboring (e.g., in the Y-direction) one another. For example, as shown in FIG. 1B, within an individual block 104, at least four (4) rows of the first cell pillar structures 116A, respectively extending in the X-direction, may be horizontally interposed, in the Y-direction, between two (2) of the slots 138 horizontally neighboring one another in the Y-direction.

As shown in FIG. 1A, horizontal dimensions, in the Y-direction, of each of the slots 138 may progressively decrease from relatively larger (e.g., wider, greater) horizontal dimensions at an uppermost vertical boundary (e.g., an uppermost end) thereof to relatively smaller (e.g., narrower) horizontal dimensions toward and at a lowermost vertical boundary (e.g., a lowermost end) thereof. Put another way, each slot 138 may exhibit tapering between horizontal cross-sectional areas of relatively vertical higher portions thereof and relatively lower portions thereof. For example, the slots 138 may individually exhibit different horizontal widths, in the Y-direction, decreasing in a downward vertical direction (e.g., negative Z-direction) from a first (e.g., uppermost) horizontal width at an upper terminal end thereof to a second (e.g., lowermost) horizontal width, relatively smaller than the first horizontal width, at a lower terminal end thereof. At least the second horizontal width of the slot 138 is less than a relatively largest (e.g., uppermost) horizontal width, in the Y-direction, of an individual second cell pillar structure 116B partially exposed by the slot 138. In some embodiments, the first horizontal width of the slot 138 and the second horizontal width of the slot 138 are each less than the largest horizontal width, in the Y-direction, of an individual second cell pillar structure 116B partially exposed by the slot 138.

Referring collectively to FIGS. 1A and 1C, the slots 138 are formed to expose (e.g., uncover) portions of the channel material 120 of respective second cell pillar structures 116B of the microelectronic device structure 100. For example, an individual slot 138 may expose the channel material 120 of each second cell pillar structure 116B of an individual row of the second cell pillar structure 116B. Forming an individual slot 138 may substantially remove a relatively vertically higher portion of the channel material 120 of respective second cell pillar structures 116B, while a relatively vertically lower portion of the channel material 120 of the respective second cell pillar structures 116B is substantially maintained (e.g., is not removed). For example, forming the slots 138 may effectuate the removal (e.g., absence) of the channel material 120 from upper portions of the second cell pillar structures 116B vertically overlapping at least two (2) (e.g., at least three (3), at least four (4)) uppermost tiers 112 of the stack structure 102. Remaining, lower portions of the channel material 120 of the second cell pillar structures 116B are exposed by the slots 138 at one or more vertical positions at or proximate a lower vertical boundary of the least two (2) (e.g., at least three (3), at least four (4)) uppermost tiers 112 of the stack structure 102. As shown in FIG. 1A, in some embodiments, the channel material 120 of the second cell pillar structures 116B is exposed by the slots 138 at one or more vertical positions within or below a vertical span of a third highest tier 112 of the stack structure 102.

Still referring collectively to FIGS. 1A and 1C, the outer material stack 118 of respective second cell pillar structures 116B may be at least partially maintained within upper portions of the second cell pillar structures 116B where the channel material 120 has been removed as a result of the formation of the slots 138. For example, for an individual row of the second cell pillar structures 116B, at least one of the materials (e.g., one or more of the charge-blocking material 124, the charge-trapping material 126, and the tunnel dielectric material 128) of the outer material stack 118 of respective second cell pillar structures 116B of the row may be maintained across substantially an entire vertical height of the slot 138 operatively associated with (e.g., horizontally overlapping and vertically extending into) the row of the second cell pillar structures 116B. One or more materials (e.g., one or more of the charge-blocking material 124, the charge-trapping material 126, and the tunnel dielectric material 128) of the outer material stack 118 of an individual second cell pillar structure 116B operatively associated with an individual slot 138 may be horizontally interposed, in the Y-direction, between the slot 138 and each of the tiers 112 of the stack structure 102 vertically overlapping the slot 138. In additional embodiments, forming an individual slot 138 may substantially remove a relatively vertically higher portion of the outer material stack 118 of respective second cell pillar structures 116B within a vertical span of the slot 138, while a relatively vertically lower portion of the outer material stack 118 of the respective second cell pillar structures 116B is substantially maintained (e.g., is not removed).

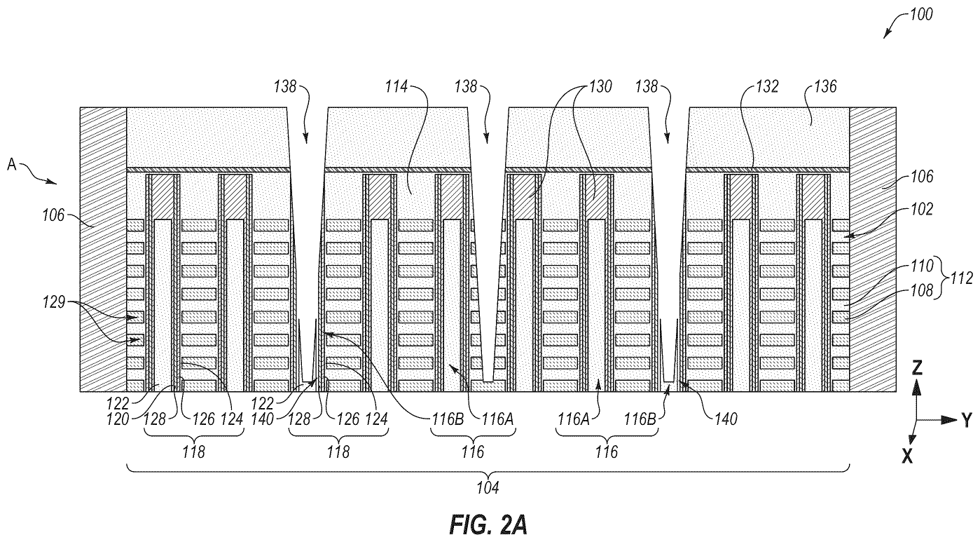

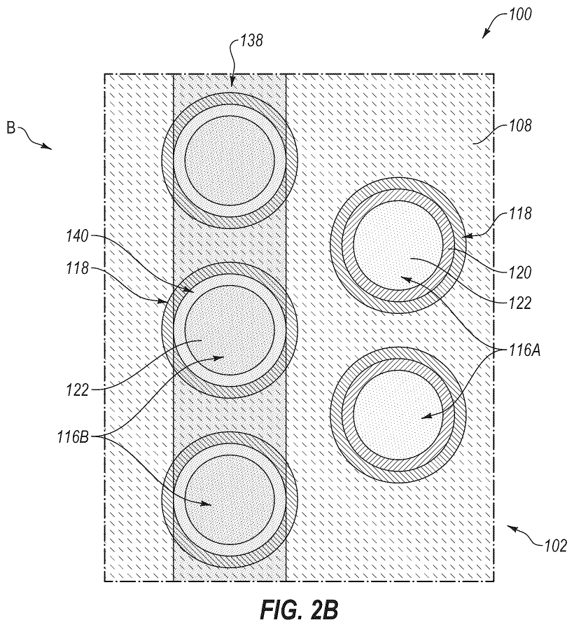

FIG. 2A is a simplified, vertical cross-sectional view of the portion A of the microelectronic device structure shown in FIGS. 1A and 1B at another processing stage of the method forming the microelectronic device following the processing stage of FIGS. 1A through 1C. As shown in FIG. 2A, remaining portions of the channel material 120 (FIGS. 1A through 1C) of the second cell pillar structures 116B may be at least partially (e.g., substantially) removed (e.g., exhumed) by way of the slots 138 to form void spaces 140 at positions (e.g., horizontal positions, vertical positions) of the portions of the channel material 120 (FIGS. 1A through 1C) remaining following the processing stage previously described with reference to FIGS. 1A through 1C. Within an individual second cell pillar structure 116B, the void space 140 may vertically extend from and be continuous with the slots 138 operatively associated with (e.g., horizontally overlapping and vertically extending into) the second cell pillar structure 116B. FIG. 2B shows a magnified view of the section B shown in FIGS. 1B and 1C at the processing stage of FIG. 2A.

The channel material 120 (FIGS. 1A through 1C) of the second cell pillar structures 116B may be at least partially removed by way of the slots 138 while substantially maintaining portions of the outer material stack 118 and the fill material 122 of the second cell pillar structures 116B remaining following the processing stage previously described with reference to FIGS. 1A through 1C. As a result, the void space 140 formed within an individual second cell pillar structure 116B may be horizontally interposed between a remainder of the fill material 122 of the second cell pillar structure 116B and a remainder of the outer material stack 118 of the second cell pillar structure 116B. In some embodiments, an individual void space 140 is formed to horizontally extend (e.g., in the Y-direction) from a remainder of the fill material 122 of a respective second cell pillar structure 116B to a remainder of the outer material stack 118 (e.g., a remainder of the tunnel dielectric material 128) of the second cell pillar structure 116B. As shown in FIG. 2B, the void space 140 may be substantially confined within a maximum horizontal area (e.g., a horizontal area at a relatively highest vertical elevation) of the slot 138 associated with the void space 140.

In some embodiments, the channel material 120 (FIGS. 1A through 1C) of the second cell pillar structures 116B is substantially removed to form the void spaces 140. Accordingly, an individual void space 140 may substantially continuously vertically extend from a respective slot 138 to a lower vertical boundary (e.g., a lower end) of the channel material 120 (FIGS. 1A through 1C) of a respective second cell pillar structure 116B prior to the removal of the channel material 120 (FIGS. 1A through 1C). For example, an individual void space 140 may be formed to vertically extend (e.g., in the Z-direction) from a first vertical position along a tapered side boundary of a respective slot 138 to a second vertical position at or below a lower vertical boundary of the stack structure 102. The void space 140 may substantially continuously vertically extend through all tiers 112 of the stack structure 102 vertically underlying a vertical position at which the void space 140 intersects (e.g., merges with) the slot 138.

In additional embodiments, the channel material 120 (FIGS. 1A through 1C) of the second cell pillar structures 116B is only partially (e.g., less than completely) removed to form the void spaces 140. Accordingly, an individual void space 140 may substantially continuously vertically extend from a respective slot 138 to a vertical position above a lower vertical boundary of the channel material 120 (FIGS. 1A through 1C) of a respective second cell pillar structure 116B prior to the removal of the channel material 120 (FIGS. 1A through IC). A further portion of the channel material 120 (FIGS. 1A through IC) may remain following the formation the void space 140. In some embodiments, the further remaining portion of the channel material 120 (FIGS. 1A through 1C) of an individual second cell pillar structure 116B may vertically underlie (e.g., in the Z-direction) and horizontally overlap (e.g., in the Y-direction) the void space 140 formed within the second cell pillar structure 116B. For example, an individual void space 140 may be formed to vertically extend (e.g., in the Z-direction) from a first vertical position along a tapered side boundary of a respective slot 138 to a second vertical position above a lower vertical boundary of the stack structure 102. The void space 140 may substantially continuously vertically extend through less than all tiers 112 of the stack structure 102 vertically underlying the vertical position at which the void space 140 intersects (e.g., merges with) the slot 138.

An upper vertical boundary of an individual void space 140 may be positioned at a vertical location along a tapered side boundary of a respective slot 138 between an upper vertical boundary and a lower vertical boundary of the slot 138. The vertical position of the upper vertical boundary of the void space 140 depends on the vertical elevation at which the channel material 120 (FIGS. 1A through 1C) of the associated second cell pillar structure 116B is exposed by the slot 138. In some embodiments, the upper vertical boundary of an individual void space 140 is located at or above a vertical midpoint of the slot 138 continuous with the void space 140. In additional embodiments, the upper vertical boundary of an individual void space 140 is located below a vertical midpoint of the slot 138 continuous with the void space 140.

The formation of the void spaces 140 within the second cell pillar structures 116B may alleviate (e.g., eliminate) undesirable coupling between the channel material 120 (FIGS. 1A through 1C) of the second cell pillar structure 116B and the conductive material 108 of the tiers 112 of the stack structure 102 during use and operation of a microelectronic device subsequently formed from the microelectronic device structure 100. The formation of the void spaces 140 may also facilitate relatively reduced capacitance between the conductive material 108 of some of the tiers 112 (e.g., word line tiers) of the stack structure 102 and the second cell pillar structures 116B during use and operation of the microelectronic device subsequently formed from the microelectronic device structure 100, which may facilitate relatively enhanced programing properties (e.g., programing time (T_{prog})) and reliability properties (e.g., device cycling degradation) for the microelectronic device relative to conventional configurations.

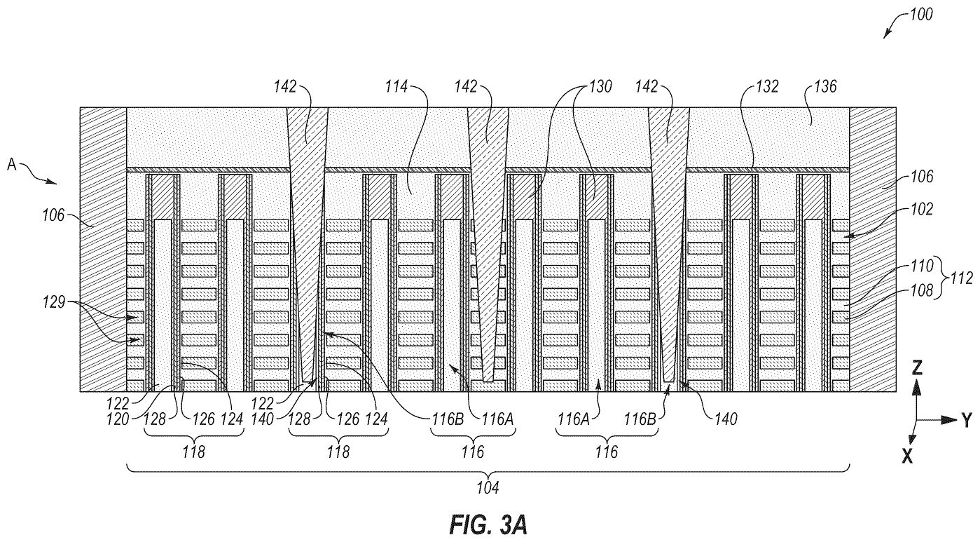

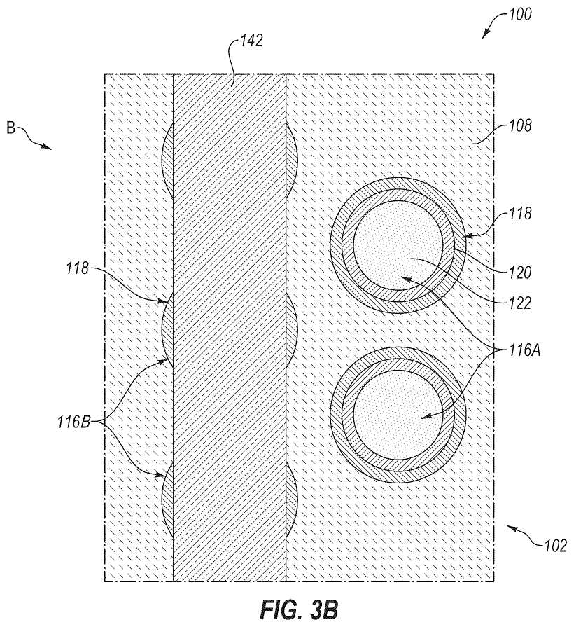

FIG. 3A is a simplified, vertical cross-sectional view of the portion A of the microelectronic device structure shown in FIGS. 1A and 1B at another processing stage of the method forming the microelectronic device following the processing stage of FIGS. 2A and 2B. As shown in FIG. 3A, additional slot structures 142 may be formed within the slots 138 (FIGS. 2A and 2B) while at least partially (e.g., substantially) maintaining the void spaces 140. Following the formation of the additional slot structures 142, the void spaces 140 may vertically extend from side surfaces of the additional slot structures 142. Portions of the side surfaces of the additional slot structures 142 may form and define upper vertical boundaries of the void spaces 140 within the second cell pillar structures 116B. FIG. 3B shows a magnified view of the section B shown in FIGS. 1B and 1C at the processing stage of FIG. 3A.

The additional slot structures 142 may comprise portions of the slots 138 (FIGS. 2A and 2B) at least partially (e.g., substantially) filled with insulative material, such as one or more of dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), dielectric nitride material (e.g., SiN_{y}), dielectric oxynitride material (e.g., SiOₓN_{y}), dielectric oxycarbide material (e.g., SiOₓC_{y}), hydrogenated dielectric oxycarbide material (e.g., SiCₓO_{y}H_{z}), and dielectric carboxynitride material (e.g., SiOₓC_{z}N_{y}). In some embodiments, the additional slot structures 142 are respectively formed of and include dielectric oxide material (e.g., SiOₓ, such as SiO₂). The additional slot structures 142 may individually be substantially homogeneous, or the slot structures 106 may individually be heterogeneous.

As shown in FIG. 3A, in some embodiments, material (e.g., insulative material) of the additional slot structures 142 does not extend into the void spaces 140. Accordingly, volumes and vertical boundaries (e.g., upper vertical boundaries, lower vertical boundaries) of the void spaces 140 following the formation of the additional slot structures 142 may be substantially the same as volumes of and vertical boundaries (e.g., upper vertical boundaries, lower vertical boundaries) of the void spaces 140 prior to the formation of the additional slot structures 142. In additional embodiments, the material (e.g., insulative material) of the additional slot structures 142 at least partially extends into the void spaces 140. Accordingly, volumes and vertical boundaries (e.g., upper vertical boundaries, lower vertical boundaries) of the void spaces 140 following the formation of the additional slot structures 142 may be different than volumes of and vertical boundaries (e.g., upper vertical boundaries, lower vertical boundaries) of the void spaces 140 prior to the formation of the additional slot structures 142. For example, an individual additional slot structure 142 may include projections vertically extending into and at least partially (e.g., less than completely or substantially completely) filling an individual void space 140 formed at the processing stage previously described herein with reference to FIGS. 2A and 2B. In some such embodiments, a vertical span (e.g., a vertical height) of such projections of such an individual additional slot structure 142 may be less than or equal to a vertical span (e.g., a vertical height) on an individual tier 112 of the stack structure 102. In addition, as shown in FIG. 3A, in some embodiments, upper surfaces of the additional slot structures 142 are formed to be substantially coplanar with an upper surface of the third dielectric material 136. In additional embodiments, the upper surfaces of the additional slot structures 142 are formed to be vertically offset (e.g., to vertically underlie, to vertically overlie) from the upper surface of the third dielectric material 136.

Thus, in accordance with embodiments of the disclosure, a microelectronic device includes a stack structure, pillar structures, and insulative slot structures. The stack structure includes blocks horizontally extending in parallel in a first direction and individually having tiers respectively including conductive material and insulative material vertically neighboring the conductive material. The pillar structures vertically extend through the blocks of the stack structure. The pillar structures respectively include a void space horizontally interposed between dielectric material and additional dielectric material. The insulative slot structures horizontally extend in parallel in the first direction. The insulative slot structures respectively horizontally overlap and vertically extend into a group of the pillar structures.

Furthermore, in accordance with embodiments of the disclosure, a method of forming a microelectronic device includes forming a microelectronic device structure. The microelectronic device structure includes a block and cell pillar structures vertically extending through the block. The block has tiers respectively including conductive material and insulative material vertically neighboring the conductive material. The cell pillar structures respectively include semiconductor material horizontally interposed between dielectric material and additional dielectric material. Slots are formed within a horizontal area of the block. The slots horizontally overlap and vertically extend into some rows of the cell pillar structures. The semiconductor material of respective ones of the cell pillar structures of the some rows of the cell pillar structures is removed by way of the slots to form a void space horizontally interposed between the dielectric material and additional dielectric material of the respective ones of the cell pillar structures. The slots are filled with further dielectric material after removing the semiconductor material. The void space formed within the respective ones of the cell pillar structures at least partially remains after filling the slots with the further dielectric material.

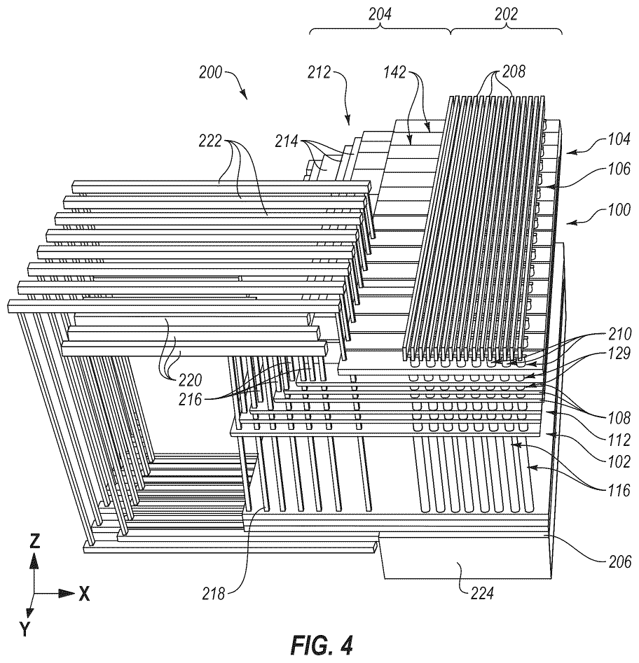

Microelectronic device structures (e.g., the microelectronic device structure 100 following the processing stage previously described with reference to FIGS. 3A and 3B) of the disclosure may be included in microelectronic devices of the disclosure. For example, FIG. 4 illustrates a partial cutaway perspective view of a portion of a microelectronic device 200 (e.g., a memory device, such as a 3D NAND Flash memory device) including the microelectronic device structure 100 following the processing stage previously described with reference to FIGS. 3A and 3B. To avoid repetition, not all features (e.g., structures, materials, regions, devices) shown in FIG. 4 are described in detail herein. Rather, unless described otherwise below, in FIG. 4, a feature designated by a reference numeral previously described with reference to one or more of FIGS. 1A through 3B will be understood to be substantially similar to the previously described feature. In addition, for clarity and ease of understanding the drawings and associated description, some features (e.g., structures, materials, regions, devices) of the microelectronic device structure 100 previously described herein are not shown in FIG. 4. However, it will be understood that any features of the microelectronic device structure 100 at the process stage previously described with reference to FIGS. 3A and 3B may be included in the microelectronic device structure 100 of the microelectronic device 200 described herein with reference to FIG. 4.

As shown in FIG. 4, the stack structure 102 of the microelectronic device 200 may include a memory array region 202 and a staircase region 204 horizontally neighboring the memory array region 202 in the X-region. Within the memory array region 202, the blocks 104 may respectively include an array of the cell pillar structures 116 (and, hence, an array of the vertically extending strings of memory cells 129). Within the staircase region 204, the blocks 104 may respectively include at least one staircase structure 212 having steps 214 defined by horizontal ends of the tiers 112 of the stack structure 102. Within an individual block 104 of the stack structure 102, the steps 214 of the staircase structure 212 of the block 104 may serve as contact locations for the conductive material 108 of the tiers 112.

The microelectronic device 200 may further include access line routing structures 220, select line routing structures 222, one or more second select gates 206 (e.g., lower select gates, source select gates (SGSs)), contact structures 216 (e.g., access line contact structures, select line contact structures), support structures 218, and digit line structures 208. The digit line structures 208 may vertically overlie and be coupled to some of the cell pillar structures 116 (and, hence, the strings of memory cells 129). In addition, the contact structures 216 may couple various features of the microelectronic device 200 to one another as shown (e.g., the select line routing structures 222 to the first (e.g., upper) select gates; the access line routing structures 220 to the conductive material 108 of the tiers 112 of the stack structure 102 underlying the first select gates and defining access line structures of the microelectronic device 200).

The microelectronic device 200 may also include a base structure 224 positioned vertically below the cell pillar structures 116 (and, hence, the strings of memory cells 129). The base structure 224 may include at least one control logic region including control logic devices configured to control various operations of other features (e.g., the strings of memory cells 129) of the microelectronic device 200. As a non-limiting example, the control logic region of the base structure 224 may further include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the base structure 224 may be coupled to a source structure, the access line routing structures 220, the select line routing structures 222, and the digit line structures 208. In some embodiments, the control logic region of the base structure 224 includes CMOS (complementary metal-oxide-semiconductor) circuitry. In such embodiments, the control logic region of the base structure 224 may be characterized as having a “CMOS under Array” (“CuA”) configuration.

Thus, in accordance with embodiments of the disclosure, a memory device includes a stack structure and dielectric slot structures. The stack structure has blocks including tiers each including conductive material vertically neighboring insulative material. The blocks respectively include strings of memory cells vertically extending through some of the tiers, and rows of pillar structures horizontally extending in parallel in a first direction and horizontally neighboring the strings of memory cells in a second direction orthogonal to the first direction. The pillar structures of respective ones of the rows individually include a void space horizontally interposed between dielectric material and additional dielectric material. The dielectric slot structures are within horizontal areas of the blocks of the stack structure and horizontally extend in parallel in the first direction. The dielectric slot structures respectively horizontally overlap and vertically extend into one of the rows of the pillar structures.

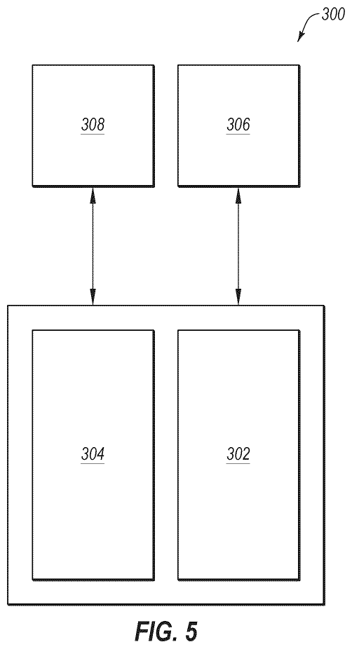

Microelectronic devices (e.g., the microelectronic device 200 (FIG. 4)) in accordance with embodiments of the disclosure may be used in embodiments of electronic systems of the disclosure. For example, FIG. 5 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 300 includes at least one memory device 302. The memory device 302 may comprise, for example, a microelectronic device (e.g., microelectronic device 200 (FIG. 4)) previously described herein. The electronic system 300 may further include at least one electronic signal processor device 304 (often referred to as a “microprocessor”). The electronic signal processor device 304 may, optionally, include a microelectronic device (e.g., the microelectronic device 200 (FIG. 4)) previously described herein. While the memory device 302 and the electronic signal processor device 304 are depicted as two (2) separate devices in FIG. 5, in additional embodiments, a single (e.g., only one) memory/processor device having the functionalities of the memory device 302 and the electronic signal processor device 304 is included in the electronic system 300. In such embodiments, the memory/processor device may include a microelectronic device (e.g., the microelectronic device 200 (FIG. 4)) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a stack structure comprising blocks horizontally extending in parallel in a first direction and individually having tiers respectively comprising conductive material and insulative material vertically neighboring the conductive material;
pillar structures vertically extending through the blocks of the stack structure, the pillar structures respectively comprising a void space horizontally interposed between dielectric material and additional dielectric material; and
insulative slot structures horizontally extending in parallel in the first direction, the insulative slot structures respectively horizontally overlapping and vertically extending into a group of the pillar structures.

2. The microelectronic device of claim 1, further comprising additional cell pillar structures vertically extending through the vertically extending through the blocks of the stack structure, the additional cell pillar structures respectively horizontally offset from the insulative slot structures in a second direction orthogonal to the first direction.

3. The microelectronic device of claim 2, wherein additional cell pillar structures respectively comprise:
the dielectric material;
the additional dielectric material; and
semiconductor material horizontally interposed between the dielectric material and the additional dielectric material.

4. The microelectronic device of claim 1, wherein the insulative slot structures only partially vertically extend through the blocks of the stack structure.

5. The microelectronic device of claim 1, wherein the insulative slot structures respectively vertically extend from an upper end above the stack structure to a lower end below an upper boundary of the void space of respective ones of the pillar structures.

6. The microelectronic device of claim 1, wherein the void space of each pillar structure of the group of the pillar structures is within a maximum horizontal area of one of the insulative slot structures horizontally overlapping and vertically extending into the group of the pillar structures.

7. The microelectronic device of claim 6, wherein the void space of each pillar structure of the group of the pillar structures vertically extends from a tapered side surface of the one of the insulative slot structures.

8. The microelectronic device of claim 1, wherein the pillar structures respectively comprise:
charge blocking material;
charge trapping material outwardly horizontally surrounded by the charge blocking material;
the dielectric material outwardly horizontally surrounded by the charge trapping material;
the void space outwardly horizontally surrounded by the dielectric material; and
the additional dielectric material outwardly horizontally surrounded by the void space.

9. The microelectronic device of claim 1, further comprising additional slot structures vertically extending substantially completely through the stack structure and horizontally alternating with the blocks of the stack structure in a second direction orthogonal to the first direction.

10. The microelectronic device of claim 1, wherein the group of the pillar structures comprises a row of the pillar structures horizontally extending in the first direction, a respective one of the insulative slot structures horizontally overlapping the row of the pillar structures in a second direction orthogonal to the first direction.

11. The microelectronic device of claim 1, wherein the insulative slot structures also respectively vertically extend through at least three other dielectric materials vertically overlying the stack structure.

12. A method of forming a microelectronic device, comprising:
forming a microelectronic device structure comprising:
a block having tiers respectively comprising conductive material and insulative material vertically neighboring the conductive material; and
cell pillar structures vertically extending through the block and respectively comprising semiconductor material horizontally interposed between dielectric material and additional dielectric material;
forming slots within a horizontal area of the block, the slots horizontally overlapping and vertically extending into some rows of the cell pillar structures;
removing the semiconductor material of respective ones of the cell pillar structures of the some rows of the cell pillar structures by way of the slots to form a void space horizontally interposed between the dielectric material and additional dielectric material of the respective ones of the cell pillar structures; and
filling the slots with further dielectric material after removing the semiconductor material, the void space formed within the respective ones of the cell pillar structures at least partially remaining after filling the slots with the further dielectric material.

13. The method of claim 12, wherein forming slots within a horizontal area of the block comprises forming the slots to horizontally extend in parallel in a first direction and to respectively be horizontally interposed between some other rows of the cell pillar structures in a second direction orthogonal to the first direction.

14. The method of claim 12, wherein forming slots within a horizontal area of the block further comprises forming the slots to partially vertically extend through portions of the block horizontally interposed between pairs of the cell pillar structures horizontally neighboring one another within the some rows of the cell pillar structures.

15. The method of claim 12, wherein forming slots within a horizontal area of the block comprises forming the slots to respectively have tapered side boundaries that expose the semiconductor material of the respective ones of the cell pillar structures of the some rows of the cell pillar structures.

16. The method of claim 12, wherein forming slots within a horizontal area of the block comprises forming the slots to vertically extend through less than or equal to about eight of the tiers of the block.

17. The method of claim 15, wherein removing the semiconductor material of respective ones of the cell pillar structures of the some rows of the cell pillar structures comprises substantially completely removing the semiconductor material.

18. The method of claim 17, wherein removing the semiconductor material of respective ones of the cell pillar structures of the some rows of the cell pillar structures comprises only partially removing the semiconductor material.

19. The method of claim 12, wherein filling the slots with further dielectric material comprises substantially completely filling the slots with the further dielectric material.

20. A memory device, comprising:
a stack structure comprising blocks including tiers each comprising conductive material vertically neighboring insulative material, the blocks respectively comprising:
strings of memory cells vertically extending through some of the tiers; and
rows of pillar structures horizontally extending in parallel in a first direction and horizontally neighboring the strings of memory cells in a second direction orthogonal to the first direction, the pillar structures of respective ones of the rows individually including a void space horizontally interposed between dielectric material and additional dielectric material; and
dielectric slot structures within horizontal areas of the blocks of the stack structure and horizontally extending in parallel in the first direction, the dielectric slot structures respectively horizontally overlapping and vertically extending into one of the rows of the pillar structures.
